(19) United States
(12) Patent Application Publication
(10) Pub. No.: US 2007/0023875 A1
(43) Pub. Date: Feb. 1, 2007

(54) Semiconductor package and manufacturing method thereof

(75) Inventors: Noboru Okane, Yokkaichi-shi (JP); Ryoji Matsushima, Yokkaichi-shi (JP); Kazuhiro Yamamori, Yokkaichi-shi (JP); Junya Sagara, Kawasaki-shi (JP); Yoshio Iizuka, Yokohama-shi (JP); Kuniyuki Oonishi, Kawasaki-shi (JP); Atsushi Yoshimura, Yokosuka-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/490,116

(22) Filed: Jul. 21, 2006

(30) Foreign Application Priority Data
Jul. 26, 2005 (JP) 2005-216168

(51) Int. Cl. H01L 23/495

(52) U.S. Cl. 257/666

(57) ABSTRACT

A semiconductor package includes a lead frame having an element mounting part and a lead part. A first semiconductor element and a second semiconductor element are sequentially stacked on a principal surface at least on one side of the element mounting part. An insulating resin layer serving as a second adhesive layer is filled between the first semiconductor element and the second semiconductor element. An element-side end portion of a first bonding wire connected to the first semiconductor element is buried in the insulating resin layer.

### CROSS-REFERENCE TO THE INVENTION

This application is based upon and claims the benefit of priority from the prior Japanese Patent Application No. 2005-216168, filed on Jul. 26, 2005; the entire contents of which are incorporated herein by reference.

### BACKGROUND OF THE INVENTION

1. Field of the Invention

The present invention relates to a semiconductor package and a manufacturing method thereof.

2. Description of the Related Art

In order to realize miniaturization, high density mounting and the like of a semiconductor device, a stacked multichip package in which a plurality of semiconductor elements are stacked and sealed in one package have been put to practical use in recent years. When prioritizing lower cost or the like of the stacked multichip package, a lead frame of low cost is used as a substrate to mount the semiconductor elements.

In the stacked multichip package having the lead frame, the plurality of semiconductor elements are sequentially stacked on an element mounting part of the lead frame via an adhesive layer, respectively. Further, an electrode pad of each semiconductor element is electrically connected to a lead part of the lead frame via a bonding wire, respectively. By packaging such a stacked structure with a sealing resin, the stacked multichip package is formed.

In the stacked multichip packaged as described above, when stacking semiconductor elements, for example, of the same shape on the lead frame, the semiconductor element on the upper side possibly interferes with the bonding wire of the semiconductor element on the lower side. Therefore, a spacer of a size smaller than the semiconductor elements is arranged between the semiconductor elements. However, in such a stacked structure, the portion below the bonding part of the semiconductor element on the upper side is comes to a hollow state, by which flexure is caused by the load when bonding depending on the thickness of the semiconductor element.

The flexure of the upper-side semiconductor element causes bonding failure, contacting failure with the bonding wire on the lower side, and soon. Further, depending on the amount of the flexure, the semiconductor element possibly suffers a crack or the like. Based on the above, the stacked multichip package using the spacer is prevented from reducing the thickness of its upper-side semiconductor element so much, so that the package is prevented from reducing its thickness. In order to prevent connection failure caused at the time of a wire bonding and the crack or the like of the semiconductor element, the upper-side semiconductor element is required to have a thickness of, for example, 70 μm or more.

In the semiconductor package mounting the plurality of semiconductor elements stacked on a circuit board, it is proposed that an insulating layer is formed on the bonding surface (under surface) of the upper-side semiconductor element to prevent the contacting failure between the bonding wire of the lower-side semiconductor element and the upper-side semiconductor element. For example, in JP-A8-288455 (KOKAI), a structure, in which an insulating resin layer and a fixed resin layer are formed sequentially on a lower-side semiconductor element and, after that, an upper-side semiconductor element is arranged to be fixed, is described. The insulating resin layer covers the bonding wire of the lower-side semiconductor element.

In JP-A 2002-222913 (KOKAI), a structure, in which a sheet formed by stacking an insulating layer of polyimide resin and an adhesive layer of epoxy resin is attached to the rear surface of the upper-side semiconductor element, and the upper-side semiconductor element is bonded onto the lower-side semiconductor element using the sheet, is described. The insulating layer prevents the contact between the bonding wire connected to the lower-side semiconductor element and the upper-side semiconductor element.

### SUMMARY OF THE INVENTION

A semiconductor package according to an embodiment of the present invention comprises: a lead frame having an element mounting part and a lead part; a first semiconductor element bonded onto the element mounting part and electrically connected to the lead part via a first bonding wire; and a second semiconductor element bonded onto the first semiconductor element via an insulating resin layer and electrically connected to the lead part via a second bonding wire, in which an end portion of the first bonding wire on a side connected to the first semiconductor element is buried in the insulating resin layer.

A semiconductor package according to another embodiment of the present invention comprises: a lead frame having an element mounting part and a lead part; a first semiconductor element bonded onto a first principal surface on a surface side of the element mounting part and electrically connected to the lead part via a first bonding wire; a second semiconductor element bonded onto the first semiconductor element via a first insulating resin layer and electrically connected to the lead part via a second bonding wire; a third semiconductor element bonded onto a second principal surface on a rear surface side of the element mounting part and electrically connected to the lead part via a third bonding wire; and a fourth semiconductor element bonded onto the third semiconductor element via a second insulating resin layer and electrically connected to the lead part via a fourth bonding wire, in which an end portion of the first bonding wire on a side connected to the first semiconductor element and an end portion of the third bonding wire on a side connected to the third semiconductor element are buried in the first and second insulating resin layers, respectively.

A manufacturing method of a semiconductor package according to still another embodiment of the present invention comprises: bonding a first semiconductor element onto a principal surface on one side of an element mounting part of a lead frame; connecting electrically the first semiconductor element to a lead part of the lead frame via a first bonding wire; softening or melting at least a part of an insulating resin layer arranged between a second semiconductor element and the first semiconductor element to bond the second semiconductor element onto the first semiconductor element while bringing an end portion of the first bonding wire on the side connected to the first semiconductor element into the insulating resin layer; and connecting electrically the second semiconductor element to the lead part of the lead frame via a second bonding wire.

### BRIEF DESCRIPTION OF THE DRAWINGS

FIG. 1 is a sectional view showing a structure of a semiconductor package according to a first embodiment of the present invention.

FIG. 2 is an enlarged sectional view showing a part of the semiconductor package shown in FIG. 1.

FIGS. 3A, 3B, 3C and 3D are sectional views showing a production process of the semiconductor package shown in FIG. 1.

FIG. 4 is a sectional view showing a structure of a semiconductor package according to a second embodiment of the present invention.

FIG. 5 is an enlarged sectional view showing a part of the semiconductor package shown in FIG. 4.

FIG. 6 is a sectional view showing a production process of the semiconductor package shown in FIG. 4.

### DESCRIPTION OF THE EMBODIMENTS

Hereinafter, embodiments to embody the present invention will be described with reference to the drawings. Note that the embodiments of the present invention will be described below based on the drawings, however, such drawings are presented for the purpose only of illustration and the present invention is not limited to the drawings.

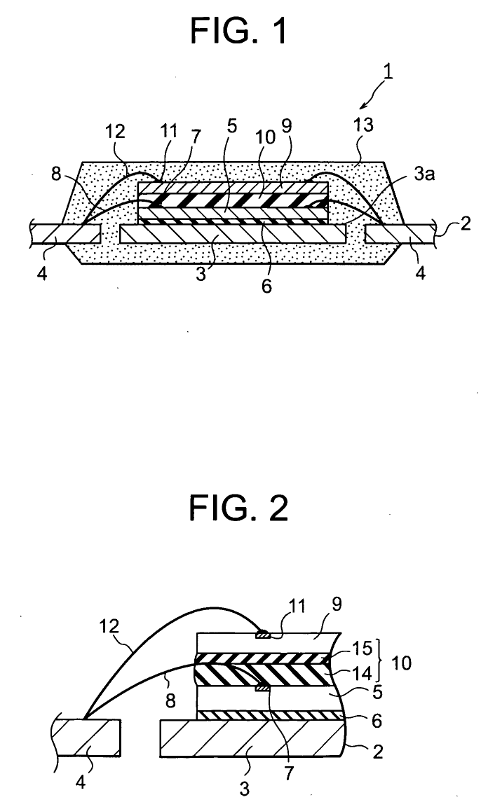

FIG. 1 is a sectional view showing a structure of a semiconductor package of a single-side stacked type according to a first embodiment of the present invention. A semiconductor package 1 shown in the drawing includes a lead frame 2 as a substrate to mount an element. The lead frame 2 has an element mounting part 3 on which a semiconductor element is bonded and a lead part 4 arranged therearound. The lead part 4 serves as a connecting portion (inner lead part) with the semiconductor element mounted on the element mounting part 3 as well as an external connection terminal (outer lead part), and is composed of a plurality of leads.

In the element mounting part 3 of the lead frame 2, a first semiconductor element 5 is bonded via a first adhesive layer 6 onto a first principal surface 3a on the surface side thereof. For the first adhesive layer 6, a general die attach member (a die attach film) made of an insulating resin may be used. A first electrode pad 7 provided on the upper surface side of the first semiconductor element 5 is connected to the lead part 4 of the lead frame 2 via a first bonding wire 8. In this manner, the first semiconductor element 5 is electrically connected to the lead part 4.

Onto the first semiconductor element 5, a second semiconductor element 9 is bonded via a second adhesive layer 10. The second adhesive layer 10 is formed by an insulating resin serving as an adhesive. A second electrode pad 11 provided on the upper surface side of the second semiconductor element 9 is connected to the lead part 4 of the lead frame 2 via a second bonding wire 12. In this manner, the second semiconductor element 9 is electrically connected to the lead part 4. The first and second semiconductor elements 5, 9 including a part (inner lead part) of the lead part 4 on the side connected to the element are sealed with a sealing resin 13 such as epoxy resin thereafter, so that the semiconductor package 1 of the single-side stacked type is formed.

Here, the second semiconductor element 9 has, for example, substantially the same shape as the first semiconductor element 5. However, the shape of the second semiconductor element 9 is not limited thereto, and in such a case as the second semiconductor element 9 interferes with the first bonding wire 8, the semiconductor package 1 according to the present embodiment is effectively applicable. The second semiconductor element 9 may have a larger shape than that of the first semiconductor element 5. Also, when arranging the second semiconductor element 9 as an offset with respect to the first semiconductor element 5, the present embodiment is applicable.

When the second semiconductor element 9 has substantially the same shape as the first semiconductor element 5, the second semiconductor element 9 inevitably exists above the first bonding wire 8, in which it becomes important to prevent the contact of these. As previously described, when the spacer of a size being smaller than those of the first semiconductor element 5 and the second semiconductor element 9 is arranged between the first semiconductor element 5 and the second semiconductor element 9, the portion below the electrode pad 11 of the second semiconductor element 9 is put into the hollow state, in which a flexure is possibly caused in the second semiconductor element 9 due to the bonding load of the second bonding wire 12.

In the semiconductor package 1 according to the present embodiment, an insulating resin serving as a second adhesive layer 10 is filled between the first semiconductor element 5 and the second semiconductor element 9. Therefore, the end portion of the first bonding wire 8 on the side connected to the first semiconductor element 5 is buried in the insulating resin layer (second adhesive layer 10). By filling the insulating resin layer (second adhesive layer 10) between the first semiconductor element 5 and the second semiconductor element 9, the flexure of the second semiconductor element 9 due to the bonding load of the second bonding wire 12 can be prevented.

Based on this, it is possible to prevent the bonding failure ascribable to the flexure of the second semiconductor element 9, the contact of the second semiconductor element 9 with the first bonding wire 8, and further the crack or the like of the second semiconductor element 9. Further, by preventing the flexure of the second semiconductor element 9 by making use of the second adhesive layer 10, the second semiconductor element 9 can be reduced in thickness. Specifically, the first and second semiconductor elements 5, 9 can be formed to have a thickness of 70 μm or below. Consequently, the semiconductor package 1 of a smaller thickness can be realized.

Further, the end portion of the first bonding wire 8 on the element side is buried in the insulating resin layer 10, so that the connection failure due to a peeling of the first bonding wire 8 can be prevented from arising in the manufacturing step, transportation step, and the like thereafter. From different viewpoints, the lead frame 2 is sent to the bonding step of the second semiconductor element 9, the connecting step of the second bonding wire 12, the resin sealing step and the like after the first bonding wire 8 is connected to the lead part 4 and the first semiconductor element 5. The end portion of the lead part 4 on the element side is not fixed, moving up and down in the transportation step or the like to add a load in the direction to pull the first bonding wire 8. However, in the present embodiment, the end portion of the first bonding wire 8 on the element side is buried in the insulating resin layer 10 to be fixed, allowing preventing the first bonding wire 8 from peeling or the like.

The distance between the first semiconductor element 5 and the second semiconductor element 9 is maintained by the insulating resin layer serving as a second adhesive layer 10. Accordingly, when bonding the second semiconductor element 9 onto the first semiconductor element 5, it becomes important to prevent the first bonding wire 8 and the second semiconductor element 9 from contacting each other. It is possible to prevent the first bonding wire 8 and the second semiconductor element 9 from contacting each other by increasing the thickness of the second adhesive layer 10 (insulating resin layer) to larger than the height (the height above the element) of the first bonding wire 8.

In the semiconductor package 1 shown in FIG. 1, the first bonding wire 8 is spaced from the under surface of the second semiconductor element 9 based on the thickness of the second adhesive layer (insulating resin layer) 10. An insulation failure and a short or the like due to the contact of the first bonding wire 8 and the second semiconductor element 9 can be prevented based on the thickness of the insulating resin layer 10. However, when aiming to obtain an effect of preventing the contact with such a structure, there is sometimes a case where the insulating resin layer 10 has an unnecessarily large thickness depending on the thickness being set. This ends up increasing the thickness of the semiconductor package 1, as a whole.

In this respect, as shown in FIG. 2, the second adhesive layer 10 having a first resin layer 14 arranged on the first semiconductor element 5 side and a second resin layer 15 arranged on the second semiconductor element 9 side is effective. Of the second adhesive layer 10 having the two-layered structure, the first resin layer 14 softens or melts at the temperature when bonding the second semiconductor element 9 to serve as an adhesive layer while allowing the first bonding wire 8 to be brought therein. Meanwhile, the second resin layer 15 maintains its layer shape against the temperature when bonding the second semiconductor element 9 to serve as an insulating layer. The second resin layer 15 prevents the insulation failure, the short or the like caused by the contact of the first bonding wire 8 and the second semiconductor element 9.

In the adhesive layer 10 of the two-layered structure, preferably, the thickness of the first resin layer 14 is set appropriately in accordance with the height of the first bonding wire 8. Assuming that the first bonding wire 8 has a height (the maximum height above the first semiconductor element 5) of 60±15 μm, the thickness of the first resin layer 14 softening or melting at the temperature when bonding is preferably 75±15 μm. Meanwhile, the thickness of the second resin layer 15 maintaining its layer shape against the temperature when bonding is preferably in the range from 5 μm to 15 μm, as an example. By adopting the second adhesive layer 10 having such a thickness, it is possible to realize the semiconductor package 1 of the smaller thickness.

To make the respective resin layers 14, 15 fulfill their functions favorably, it is desirable that the first resin layer 14 has a viscosity (viscosity at the time of bonding) of 1 kPa·s or more and 100 kPa·s or less at the temperature when bonding. When the viscosity of the first resin layer 14 at the time of bonding is below 1 kPa·s, the adhesive resin is too soft and possibly runs over the end surface of the element. On the other hand, when the viscosity of the first resin layer 14 at the time of bonding is over 100 kPa·s, it is too hard and possibly causes deformation, connection failure, or the like of the first bonding wire 8. Preferably, the viscosity of the first resin layer 14 at the time of bonding is 1 kPa·s to 50 kPa·s.

The viscosity (viscosity at the time of bonding) of the second resin layer 15 is preferably 130 kPa·s or more. When the viscosity of the second resin layer 15 at the time of bonding is below 130 kPa·s, it is impossible for the second resin layer 15 to maintain its shape of layer when bonding the second semiconductor element 9 to the first semiconductor element 5, in which the function of the second resin layer 15 as an insulating layer becomes impaired. Preferably, the viscosity of the second resin layer 15 at the time of bonding is 1000 kPa·s or below.

The second adhesive layer 10 of the two-layered structure as described above can be obtained by stacking the first resin layer 14, which is formed by an epoxy resin layer adjusted to soften or melt, for example, at the temperature when bonding, and the second resin layer 15, which is formed by a polyimide resin layer, silicon resin layer, or the like capable of maintaining its shape of layer against the temperature when bonding, to form an adhesive film of a two-layered structure, and by attaching the adhesive film to the rear surface (surface for bonding) of the second semiconductor element 9 in advance.

Note that, when the adhesive film of the two-layered structure made of different materials is used, the elements possibly peel from each other after the bonding step of the second semiconductor element 9, the production cost required for the bonding possibly increases, or other problem possibly arises, on the basis of the difference in thermal expansion coefficients between the first resin layer 14 and the second resin layer 15. Therefore, for the first and second resin layers 14, 15 composing the adhesive layer 10 of the two-layered structure, preferably, insulating resins of the same materials are employed. As such an insulating resin, there is a thermosetting resin such as epoxy resin, as an example.

When the first resin layer 14 and the second resin layer 15 are formed using the same material such as the same composition of the thermosetting resin varnish, their behaviors (functions) at the temperature when bonding can be mutually differentiated by setting a different drying temperature or a different drying time when forming the first resin layer 14 and the second resin layer 15, respectively. In other words, it is possible to obtain the first resin layer 14 serving as a softening or melting layer and the second resin layer 15 serving as an insulating layer from the same composition of the insulating resin.

For instance, after coating epoxy resin varnish (A stage) on a base, the coated layer is dried at 150° C. to form the second resin layer 15 in the semihard state (B stage). Subsequently, the same epoxy resin varnish (A stage) is coated again on the second resin layer 15 and the coated layer is dried at 130° C. to form the first resin layer 14 in the semihard state (B stage). The resin layer of the two-layered structure is peeled from the base to be used as an adhesive film. The adhesive film is preferably used by being attached beforehand to the rear surface (surface for bonding) side of the second semiconductor element 9.

When a heating is performed at a temperature being the drying temperature of the first resin layer 14 or more (130° C. or higher) and the drying temperature of the second resin layer 15 or lower (150° C. or lower), the first resin layer 14 softens or melts while the second resin layer 15 maintains its layer shape. Accordingly, by setting the bonding temperature of the second semiconductor element 9 to be within the temperature range (for example, 130° C. or higher and 150° C. or lower) based on the forming temperature (drying temperature) of the respective resin layers 14, 15, it is possible to soften or melt the first resin layer 14 while the second resin layer 15 serves as an insulating layer.

Note that, in FIG. 1, the description was given of the structure in which two pieces of semiconductor elements 5, 9 are stacked, however, the number of the semiconductor elements to be stacked is not limited thereto. The number of elements to be stacked may be three or more. When three or more semiconductor elements are stacked to form the semiconductor package, a structure, in which the insulating resin layer is filled between the semiconductor elements while burying the element-side end portion of the bonding wire of the lower-side semiconductor element in the insulating resin layer, is adopted. Note that, when the third semiconductor element from the bottom and the semiconductor element thereabove if any is/are sufficiently smaller than those of the other semiconductor elements, the structure is not limited thereto.

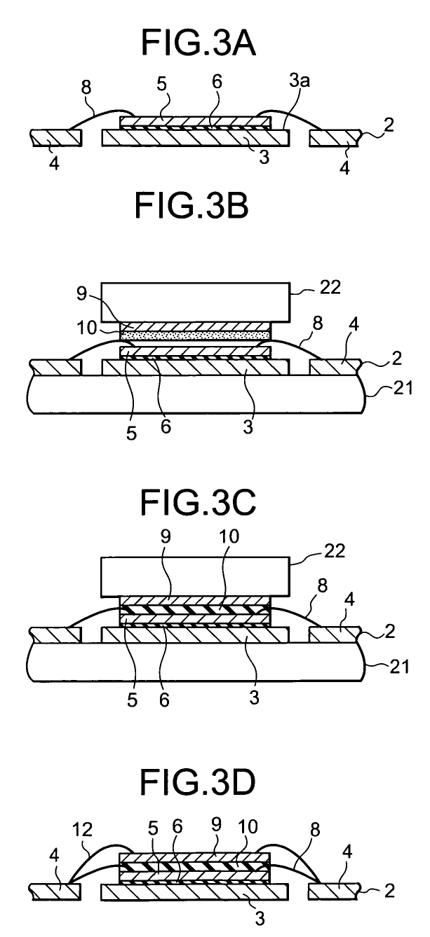

The above-described semiconductor package 1 according to the first embodiment is manufactured as described below, as an example. A production process of the semiconductor package 1 will be described with reference to FIG. 3A to FIG. 3D. First, as shown in FIG. 3A, the first semiconductor element 5 is bonded onto the first principal surface 3a of the element mounting part 3 of the lead frame 2 using the first adhesive layer 6. Subsequently, the lead part 4 of the lead frame 2 and the first semiconductor element 5 are electrically connected with the first bonding wire 8 by performing the wire bonding step. The bonding step of the first semiconductor element 5 and the wire bonding step are performed in the same manner as of conventional ones.

Subsequently, the second semiconductor element 9 is bonded onto the first semiconductor element 5 via the second adhesive layer 10. First, the lead frame 2 having the first semiconductor element 5 bonded thereto is placed on a stage (heating stage) 21 carrying a heating mechanism as shown in FIG. 3B. The first semiconductor element 5 is directly heated by the heating stage 21 via the lead frame 2. The heating temperature for the first semiconductor element 5 is appropriately set in accordance with the softening or melting temperature of the second adhesive layer 10. When applying the adhesive film of the two-layered structure to the second adhesive layer 10, the heating temperature is set in accordance with the softening or melting temperature of the first resin layer 14.

Meanwhile, the second adhesive layer 10 is formed on the rear surface of the second semiconductor element 9. The second adhesive layer 10 is formed by attaching a semihard adhesive film, for example, onto the rear surface of the second semiconductor element 9. Note that the second adhesive layer 10 may be arranged on the first semiconductor element 5. The second semiconductor element 9 having the second adhesive layer 10 is arranged above the first semiconductor element 5 by being absorbed and held by an adsorber 22, as shown in FIG. 3B. Here, although the adsorber 22 may be the one with or without the heating mechanism, the second adhesive layer 10 is preferably heated from the heating stage 21 side.

Subsequently, the second semiconductor element 9 arranged above the first semiconductor element 5 is gradually moved downward. At this time, even when the second semiconductor element 9 is not heated directly by the adsorber 22, the first semiconductor element 5 is already heated up to a predetermined bonding temperature, so that the second adhesive layer 10 softens by being heated by the radiant heat from the first semiconductor element 5.

When the second semiconductor element 9 is moved downward further to contact the first bonding wire 8, the heat transfer arises with the first bonding wire 8, so that the circumference of the contact portion of the second adhesive layer 10 and the first bonding wire 8 further softens. Accordingly, with the heating only by the heating stage 21, the deformation and connection failure of the first bonding wire 8 caused by the second adhesive layer 10 can be prevented in similar fashion. Further, the layer shape of the second adhesive layer 10 can be maintained preferably.

When the second semiconductor element 9 is moved downward furthermore, as shown in FIG. 3C, the second adhesive layer 10 contacts the first semiconductor element 5, so that the second adhesive layer 10 softens or melts entirely by the heat from the first semiconductor element 5. When the second semiconductor element 9 is moved downward, the first bonding wire 8 locally heats the second adhesive layer 10 with the temperature of itself to be brought into the second adhesive layer 10.

In the downward movement step of the second semiconductor element 9, a slight space is generated below the first bonding wire 8. However, since the second adhesive layer 10 contacts the first semiconductor element 5 to be heated, the softened or melted resin (thermosetting resin composing the second adhesive layer 10) flows into the space below the first bonding wire 8. With this, it is preventable that the portion below the first bonding wire 8 is not filled with the resin.

As described above, when softening the second adhesive layer 10 by the radiant heat from the first semiconductor element 5 and the heat transfer from the first bonding wire 8, too fast downward movement of the second semiconductor element 9 possibly leads to an insufficient softening of the second adhesive layer 10 by the radiant heat from the first semiconductor element 5 and the like. Accordingly, the downward speed of the second semiconductor element 9 is preferably in the range of 0.1 mm/s or more and 20 mm/s or less. When the starting position for the downward movement of the second semiconductor element 9 is too close to the first semiconductor element 5, possibly, the second adhesive layer 10 is not heated sufficiently by the radiant heat from the first semiconductor element 5 and the like. The starting position for the downward movement for the second semiconductor element 9 is, preferably, at least 0.5 mm above from the first semiconductor element 5.

Subsequently, adequate pressure is applied to the second semiconductor element 9 while continuously heating the first semiconductor element 5 and the second adhesive layer 10 by the heating stage 21. With the pressure applied to the second semiconductor element 9, the fluidity of the second adhesive layer 10 increases, so that the adhesive resin can be filled surely in the space below the first bonding wire 8. By heating further to thermoset the second adhesive layer 10 while it is in such a state, the second semiconductor element 9 can be bonded onto the first semiconductor element 5 favorably (FIG. 3C). Moreover, it is also possible to favorably bring the element-side end portion of the first bonding wire 8 into the second adhesive layer (insulating resin layer) 10.

After that, as shown in FIG. 3D, the wire bonding step is performed to the second semiconductor element 9 bonded onto the first semiconductor element 5 to electrically connect the lead part 4 of the lead frame 2 and the second semiconductor element 9 with the second bonding wire 12. Further, the first and second semiconductor elements 5, 9 are sealed by the sealing resin 13, and the semiconductor package 1 as shown in FIG. 1 is obtained. Note that, when stacking three or more semiconductor elements, the same step as the above-described bonding step of the second semiconductor element 9 may be repeated.

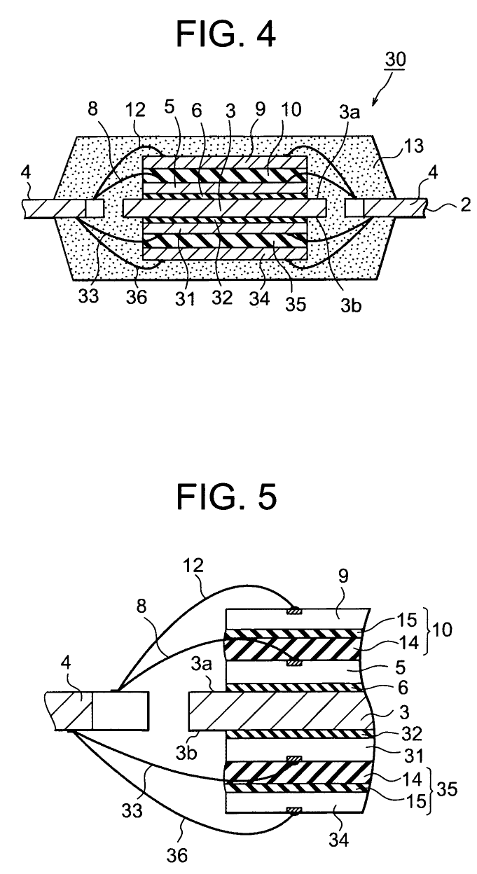

Next, the description will be given of a semiconductor package according to a second embodiment of the present invention with reference to FIG. 4 and FIG. 5. FIG. 4 is a sectional view showing a structure of the semiconductor package of a double-side stacked type according to the second embodiment. Note that the same numerical references as of the previously-described first embodiment will be used to denote the same portions as of the first embodiment and the description thereof will be omitted partially.

A semiconductor package 30 shown in FIG. 4 includes the element mounting part 3 and the lead frame 2 having the lead part 4 as in the first embodiment. In the element mounting part 3 of the lead frame 2, the first semiconductor element 5 is bonded via the first adhesive layer 6 on the first principal surface 3a on the surface side. The first semiconductor element 5 is connected to the lead part 4 of the lead frame 2 via the first bonding wire 8. Onto the first semiconductor element 5, the second semiconductor element 9 is bonded via the second adhesive layer 10. The second semiconductor element 9 is connected to the lead part 4 of the lead frame 2 via the second bonding wire 12.

Further, in the element mounting part 3 of the lead frame 2, a third semiconductor element 31 is bonded via a third adhesive layer 32 onto a second principal surface 3b on the rear surface side. The third semiconductor element 31 is connected to the lead part 4 of the lead frame 2 via a third bonding wire 33. Onto the third semiconductor element 31, a fourth semiconductor element 34 is bonded via a fourth adhesive layer 35. The fourth semiconductor element 34 is connected to the lead part 4 of the lead frame 2 via a fourth bonding wire 36.

After that, the first, second, third and fourth semiconductor elements 5, 9, 31, 34 including a part of the lead part 4 on the side connected to the element (inner lead part) are sealed using the sealing resin 13 such as epoxy resin, so that the semiconductor package 30 of the double-side stacked type is formed. Note that the element mounting part 3 of the lead frame 2 on the first principal surface 3a side has the same structure as of the first embodiment.

The first semiconductor element 5 and the second semiconductor element 9, and the third semiconductor element 31 and the fourth semiconductor element 34 have substantially the same shape, respectively. Between the respective elements (between the first and second semiconductor elements 5, 9 and between the third and fourth semiconductor elements 31, 34), the insulating resins serving as the second and fourth adhesive layers 10, 35 are filled, respectively. The end portion of the first bonding wire 8 on the side connected to the first semiconductor element 5 and the end portion of the third bonding wire 33 on the side connected to the third semiconductor element 31 are buried in the insulating resin layers (the second and fourth adhesive layers 10, 35), respectively.

As shown in FIG. 5, the second and fourth adhesive layers 10, 35 include the first resin layer 14 softening or melting at the temperature when bonding the second and fourth semiconductor elements 9, 34, respectively, and the second resin layer 15 maintaining its layer shape against the temperature when bonding the second and fourth semiconductor elements 9, 34, respectively. Note that the second and fourth adhesive layer 10, 35 may be formed by an insulating resin layer of a single-layered structure, respectively. At that case, the first and third bonding wires 8, 33 are insulated from the second and fourth semiconductor elements 9, 34, based on the thickness of the insulating resin layers 10, 35, respectively.

The arrangement positions and functions of the first and second resin layers 14, 15 in the second adhesive layer 10 are the same as shown in the first embodiment. The same is applicable to the first and second resin layers 14, 15 in the fourth adhesive layer 35. The first resin layer 14 in the fourth adhesive layer 35 is arranged on the third semiconductor element 31 side to soften or melt at the temperature when bonding to thereby serve as an adhesive layer as well as a layer to bring the third bonding wire 33 thereinto. The second resin layer 15 is arranged on the fourth semiconductor element 34 side to serve as the insulating layer against the third bonding wire 33. The specific structures of the two-layered adhesive layers 10, 35 are preferably the same as of the first embodiment.

By filling between the respective elements (between the first and second semiconductor elements 5, 9, and between the third and fourth semiconductor elements 31, 34) with the respective insulating resin layers (the second and fourth adhesive layers 10, 35), the flexures of the semiconductor elements 9, 34 caused by the bonding loads of the second and fourth bonding wires 12, 36 can be prevented, respectively. Based on this, the bonding failure and the crack of the semiconductor elements 9, 34 or the like caused by the flexures of the upper-side semiconductor elements 9, 34 can be prevented. Further, the flexures of the semiconductor elements 9, 34 are prevented by the adhesive layers 10, 34, so that the semiconductor elements 9, 34 can be reduced in thickness. Specifically, the semiconductor elements 5, 9, 31, 34 can be formed to have a thickness of 70 μm below. Consequently, the semiconductor package 30 of a smaller thickness can be realized.

Above all, even when the lead frame 2 applies the double-side stacked structure, the thickness of the entire package can be prevented from increasing by reducing the thicknesses of the respective semiconductor elements 5, 9, 31, 34. Also, the adhesive layers (insulating resin layers) 10, 35 contribute to reduce the thickness of the entire package by enabling to bond the respective elements favorably without causing loose connection or the like with the bonding wire and without using any spacer. Based on the above, the semiconductor package 30 of the double-side stacked type, in which the semiconductor element is densely packed and reduced in thickness, can be provided.

Since the element-side end portions of the first and third bonding wires 8, 33 are buried in the insulating resin layers 10, 35, respectively, so that the connection failure due to the peeling or the like of the bonding wires 8, 33 can be prevented in the manufacturing step, transportation step, and the like thereafter. In particular, the first bonding wire 8 is sent to the bonding step of the third and fourth semiconductor elements 31, 34, the connecting step of the third and fourth bonding wires 33, 36, the resin sealing step, and the like in addition to the bonding step of the second semiconductor element 9 and the connecting step of the second bonding wire 12 after connected to the lead part 4 and the first semiconductor element 5. Such a force as peels the bonding wire is applied to the element-side end portion of the first bonding wire 8 through these respective steps, the transportation step, and the like.

Under such a circumstance, however, the element-side end portion of the first bonding wire 8 is buried in the insulating resin layer 10 to be fixed, allowing preventing the first bonding wire 8 from peeling or the like. The similar force is applied to the element-side end portion of the third bonding wire 33, whereas the portion is also buried in the insulating resin layer 35 to be fixed, allowing preventing the third bonding wire 33 from peeling or the like. Hence, the semiconductor package 30 of the double-side stacked type can be improved in reliability, production yield, and the like.

Note that, in FIG. 4, the description was given of the structure in which two pieces of semiconductor elements are stacked on both the surfaces of the lead frame 2, respectively, however, the number of semiconductor elements to be stacked is not limited thereto. The number of elements to be stacked may be three or more. When three or more semiconductor elements are stacked to form the semiconductor package, the same effect as in the above-described embodiment can be obtained by applying the structure, in which the insulating resin layer is filled between the semiconductor elements while burying the element-side end portion of the bonding wire of the lower-side semiconductor element in the insulating resin layer.

The above-described semiconductor package 30 of the second embodiment is manufactured by applying the steps similar to those of the first embodiment. Specifically, by applying the production process shown in FIG. 3A to FIG. 3D, the first semiconductor element 5 and the second semiconductor element 9 are sequentially stacked and mounted on the lead frame 2. After the lead part 4 and the second semiconductor element 9 are connected with the second bonding wire 12, these are reversed to orient the second principal surface 3b of the element mounting part 3 upward.

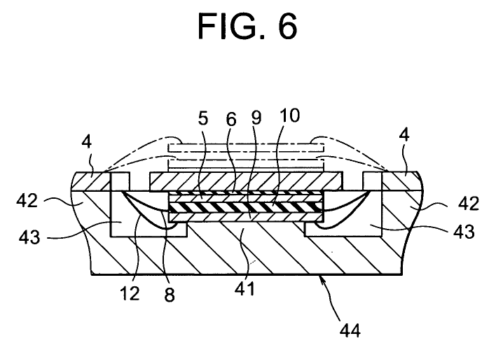

At this time, the first and second semiconductor elements 5, 9 are connected to the bonding wires 8, 12, respectively. Therefore, for instance, as shown in FIG. 6, the bonding step of the third and fourth semiconductor elements 31, 34 and the connecting step of the third and fourth bonding wires 33, 36 are carried out with the use of a fixture 44 provided with a first supporting portion 41 supporting the lead part 4, a second supporting portion 42 supporting the stacked semiconductor elements 5, 9, and a recessed portion 43 to accommodate the bonding wires 8, 12. In this manner, the highly-reliable semiconductor package 30 of the double-side stacked type can be manufactured with high yield.

It should be understood that the present invention is not limited to the above-described respective embodiments, and is applicable to various semiconductor package of the stacked type mounting a plurality of semiconductor elements on single or double surface(s) of the lead frame. Such semiconductor packages are also within the scope of the present invention. Further, the embodiments according to the present invention can be expanded or modified within the technical spirit of the present invention and the expanded or modified embodiment is also within the technical scope of the present invention.

What is claimed is:

1. A semiconductor package, comprising:
a lead frame having an element mounting part and a lead part;
a first semiconductor element bonded onto the element mounting part and electrically connected to the lead part via a first bonding wire; and
a second semiconductor element bonded onto the first semiconductor element via an insulating resin layer and electrically connected to the lead part via a second bonding wire,
wherein an end portion of the first bonding wire on a side connected to the first semiconductor element is buried in the insulating resin layer.

2. The semiconductor package as set forth in claim 1,
wherein the first and second semiconductor element have a thickness of 70 μm or below.

3. The semiconductor package as set forth in claim 1,
wherein the second semiconductor element has substantially a same shape as the first semiconductor element.

4. The semiconductor package as set forth in claim 1,
wherein the insulating resin layer has a first resin layer arranged on the first semiconductor element side and a second resin layer arranged on the second semiconductor element side, and the end portion of the first bonding wire on the side connected to the first semiconductor element is buried in the first resin layer.

5. The semiconductor package as set forth in claim 4,
wherein the first resin layer softens or melts at a temperature when bonding the second semiconductor element to serve as an adhesive layer and a layer to bring the first bonding wire therein, and the second resin layer maintains a layer shape against the temperature when bonding to serve as an insulating layer.

6. The semiconductor package as set forth in claim 5,
wherein the first and second resin layers are composed of a same resin material exhibiting different viscosity with respect to the temperature when bonding.

7. The semiconductor package as set forth in claim 1,
wherein the first bonding wire is spaced from an under surface of the second semiconductor element based on a thickness of the insulating resin layer.

8. A semiconductor package, comprising:
a lead frame having an element mounting part and a lead part;
a first semiconductor element bonded onto a first principal surface on a surface side of the element mounting part and electrically connected to the lead part via a first bonding wire;
a second semiconductor element bonded onto the first semiconductor element via a first insulating resin layer and electrically connected to the lead part via a second bonding wire,
a third semiconductor element bonded onto a second principal surface on a rear surface side of the element mounting part and electrically connected to the lead part via a third bonding wire; and
a fourth semiconductor element bonded onto the third semiconductor element via a second insulating resin layer and electrically connected to the lead part via a fourth bonding wire,
wherein an end portion of the first bonding wire on a side connected to the first semiconductor element and an end portion of the third bonding wire on a side connected to the third semiconductor element are buried in the first and second insulating resin layers, respectively.

9. The semiconductor package as set forth in claim 8,
wherein the first, second, third, and fourth semiconductor elements have a thickness of 70 μm or below.

10. The semiconductor package as set forth in claim 8,
wherein the second and fourth semiconductor elements have substantially a same shape as the first and third semiconductor element, respectively.

11. The semiconductor package as set forth in claim 8,
wherein the first and second insulating layers have a first resin layer arranged on the first semiconductor element side or the third semiconductor element side and a second resin layer arranged on the second semiconductor element side or the fourth semiconductor element side, respectively, and the end portion of the first bonding wire on the side connected to the first semiconductor element and the end portion of the third bonding wire on the side connected to the third semiconductor element are buried in the first resin layers, respectively.

12. The semiconductor package as set forth in claim 11,
wherein the first resin layer softens or melts at a temperature when bonding the second semiconductor element or the fourth semiconductor element to serve as an adhesive layer and a layer to bring the bonding wire therein, and the second resin layer maintains a layer shape against the temperature when bonding to serve as an insulating layer.

13. The semiconductor package as set forth in claim 12,
wherein the first and second resin layers are composed of a same resin material exhibiting different viscosity with respect to the temperature when bonding.

14. The semiconductor package as set forth in claim 8,
wherein the first and third bonding wires are spaced from the under surfaces of the second and fourth semiconductor elements based on the thicknesses of the first ant second insulating resin layers, respectively.

15. A manufacturing method of a semiconductor package, comprising:
bonding a first semiconductor element onto a principal surface on one side of an element mounting part of a lead frame;
connecting electrically the first semiconductor element to a lead part of the lead frame via a first bonding wire;
softening or melting at least a part of an insulating resin layer arranged between a second semiconductor element and the first semiconductor element to bond the second semiconductor element onto the first semiconductor element while bringing an end portion of the first bonding wire on the side connected to the first semiconductor element into the insulating resin layer; and
connecting electrically the second semiconductor element to the lead part of the lead frame via a second bonding wire.

16. The manufacturing method as set forth in claim 15,
wherein the first and second semiconductor elements have a thickness of 70 μm or below.

17. The manufacturing method as set forth in claim 15,
wherein the insulating resin layer has a first resin layer arranged on the first semiconductor element side and softening or melting at a temperature when bonding the second semiconductor element and a second resin layer arranged on the second semiconductor element side and maintaining a layer shape against the temperature when bonding.

18. The manufacturing method as set forth in claim 17,
wherein the first and second resin layers are composed of a same resin material exhibiting different viscosity with respect to the temperature when bonding.

19. The manufacturing method as set forth in claim 15, further comprising:
bonding a third semiconductor element onto a principal surface on the other side of the element mounting part of the lead frame;
connecting electrically the third semiconductor element to the lead part of the lead frame via a third bonding wire;
softening or melting at least a part of an insulating resin layer arranged between a fourth semiconductor element and the third semiconductor element to bond the fourth semiconductor element onto the third semiconductor element while bringing an end portion of the third bonding wire on the side connected to the third semiconductor element into the insulating resin layer;
connecting electrically the fourth semiconductor element to the lead part of the lead frame via a fourth bonding wire.

20. The manufacturing method as set forth in claim 19,
wherein the third and fourth semiconductor elements have a thickness of 70 μm or below.
